(19) United States
(12) Patent Application Publication
(10) Pub. No.: US 2019/0319381 A1
(43) Pub. Date: Oct. 17, 2019

(54) CONNECTOR FORMING SHIELDING SPACE AND ELECTRONIC DEVICE HAVING THE SAME

(71) Applicant: Samsung Electronics Co., Ltd., Gyeonggi-do (KR)

(72) Inventors: Jungje BANG, Gyeonggi-do (KR); Seungju KIM, Gyeonggi-do (KR); Taewoo KIM, Gyeonggi-do (KR); Bongkyu MIN, Gyeonggi-do (KR); Bongchoon PARK, Gyeonggi-do (KR); Jonggu PARK, Gyeonggi-do (KR); Jonghan PARK, Gyeonggi-do (KR); Jinyong PARK, Gyeonggi-do (KR); Hoyeon SEO, Gyeonggi-do (KR); Jaeheung YE, Gyeonggi-do (KR); Hyelim YUN, Gyeonggi-do (KR); Hyeongju LEE, Gyeonggi-do (KR); Hyoungsoo JUNG, Gyeonggi-do (KR)

(21) Appl. No.: 16/384,465

(22) Filed: Apr. 15, 2019

(30) Foreign Application Priority Data
Apr. 13, 2018 (KR) 10-2018-0043254

(51) Int. Cl. H01R 12/71; H01R 13/41; H01R 13/6596; H05K 7/14; H05K 1/14; H05K 1/18; H05K 1/02

(52) U.S. Cl. CPC H01R 12/712; H01R 13/41; H01R 13/6596; H05K 7/1427; H05K 2201/042; H05K 1/181; H05K 1/0216; H05K 2201/10159; H05K 1/144

(57) ABSTRACT

An electronic device includes a housing, a first board disposed inside the housing and including a first signal line and a first ground, a second board disposed on the first board and including a second signal line and a second ground, a plurality of connectors interposed between the first board and the second board, and a first electronic component disposed inside a space defined by the first board, the second board, and the plurality of connectors. Each of the plurality of connectors includes an insulating member, at least one conductive pin having at least a portion surrounded by the insulating member, and a metal plate electrically connecting the first ground of the first board with the second ground of the second board and formed on an outer sidewall of the insulating member. A first signal pin of conductive pins included in the plurality of connectors electrically connects the first signal line of the first board and the second signal line of the second board with the first electronic component. The first electronic component is electrically shielded against an outside of the space by the first ground of the first board, the second ground of the second board, and the metal plate.

### CROSS-REFERENCE TO RELATED APPLICATION(S)

This application is based on and claims priority under 35 U.S.C. § 119 to Korean Patent Application No. 10-2018-0043254, filed on Apr. 13, 2018, in the Korean Intellectual Property Office, the disclosure of which is incorporated by reference herein its entirety.

### BACKGROUND

### 1. Field

The present disclosure relates generally to a connector forming a shielding space and an electronic device having the same.

### 2. Description of Related Art

An electronic device may include a board (typically a printed circuit board (PCB)) on which a plurality of electronic components are mounted. An electronic device, such as a smartphone, is equipped with various functions, and a clock frequency of such an electronic component may be raised to increase a data transfer rate of electronic components.

An electromagnetic interference (EMI) may be caused by an electronic component operating at the high frequency, and an operating failure of the electronic device may be caused due to the EMI. To suppress the EMI, a shielding may be disposed along a partial area of the board. The shielding can may be formed of a metal material and may cover the electronic component.

A size of the board may be reduced to reduce the size of the electronic device. When the shielding is additionally included, it may be difficult to reduce the mounting areas for including parts. Accordingly, it may be advantageous to provide an electronic device having a board that is reduced in size while suppressing an EMI without including a shielding can.

### SUMMARY

The present disclosure has been made to address the above-mentioned problems and disadvantages, and to provide at least the advantages described below.

In accordance with an aspect of the present disclosure, an electronic device includes a housing, a first board disposed inside the housing and including a first signal line and a first ground, a second board disposed on the first board and including a second signal line and a second ground, a plurality of connectors interposed between the first board and the second board, and a first electronic component disposed inside a space defined by the first board, the second board, and the plurality of connectors. Each of the plurality of connectors includes an insulating member, at least one conductive pin having at least a portion surrounded by the insulating member, and a metal plate electrically connecting the first ground of the first board with the second ground of the second board and formed on an outer sidewall of the insulating member. A first signal pin of conductive pins included in the plurality of connectors electrically connects the first signal line of the first board and the second signal line of the second board with the first electronic component. The first electronic component is electrically shielded against an outside of the space by the first ground of the first board, the second ground of the second board, and the metal plate.

In accordance with another aspect of the present disclosure, a connector includes an insulating member including a first surface, a second surface facing the first surface, and a third surface interposed between the first surface and the second surface, a plurality of conductive pins, each conductive pin including at least a portion surrounded by the insulating member and opposite end portions formed on the first surface and the second surface, respectively, and a metal plate formed on the third surface.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is an exploded perspective view of an electronic device, according to an embodiment;

FIG. 2 is a perspective view of first and second boards of the electronic device, according to an embodiment;

FIG. 3 is a plan view of the first board of the electronic device, according to an embodiment;

FIG. 4 is a plan view of the second board of the electronic device, according to an embodiment;

FIG. 5 is a sectional view of a shielding space of the electronic device, according to an embodiment;

FIG. 6 is a perspective view of a connector of the electronic device, according to an embodiment;

FIG. 7 is a view illustrating the layout of the board and the battery of the electronic device, according to an embodiment; and

FIG. 8 is a block diagram illustrating an electronic device in a network environment, according to an embodiment.

### DETAILED DESCRIPTION

Various embodiments of the present disclosure are described with reference to the accompanying drawings. However, various embodiments of the present disclosure are not limited to particular embodiments, and it should be understood that modifications, equivalents, and/or alternatives of the embodiments described herein can be variously made. With regard to description of drawings, similar components may be marked by similar reference numerals.

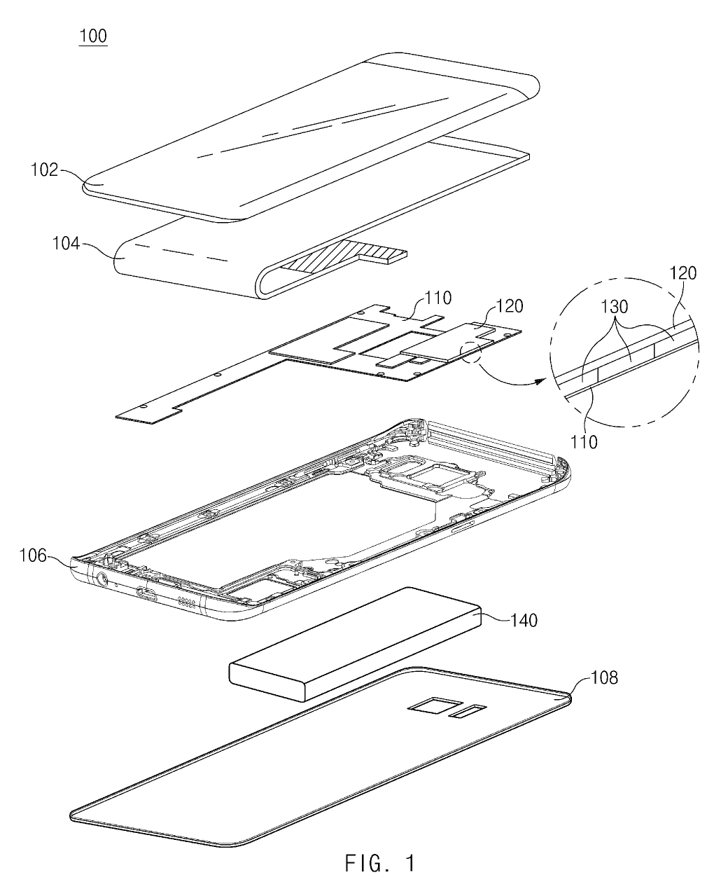

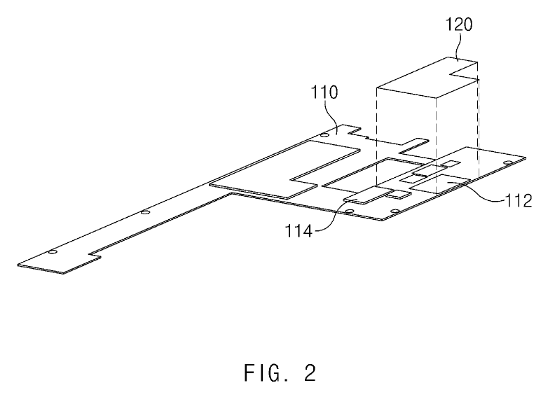

FIG. 1 is an exploded perspective view of an electronic device, according to an embodiment, and FIG. 2 is a perspective view of first and second boards of the electronic device, according to an embodiment.

Referring to FIG. 1, an electronic device 100 includes a housing 106, a first board 110 disposed inside the housing 106, a second board 120 disposed on the first board 110, a connector 130 interposed between the first board 110 and the second board 120, a battery 140 to supply power to the electronic device 100, and a display 104 disposed on a front surface of the electronic device 100.

The housing 106 may protect a part of the electronic device 100, which is disposed inside the housing 106. The housing 106 may include a window glass 102 disposed on the front surface of the housing 106 and a back cover 108. The display 104 may be disposed under the window glass 102, and the battery 140 may be disposed on the back cover 108.

The first board 110 may include a plurality of electronic components and wirings electrically connected with the electronic components, respectively. The electronic components may include an active element and a passive element. The electronic components may be formed on one surface of the first board 110. One surface of the first board 110 may refer to a surface facing the display 104 of FIG. 1.

Referring to FIG. 2, the electronic components included in the first board 110 includes a first electronic component 112 and a third electronic component 114. The first electronic component 112 and the third electronic component 114 may be mounted on the one surface of the first board 110. The first electronic component 112 may be interposed between the first board 110 and the second board 120. The third electronic component 114 may be disposed on the first board 110 while being disposed outside the second board 120.

The second board 120 may include a plurality of electronic components and wirings electrically connected with electronic components, respectively. The electronic components may include an active element and a passive element. The second board 120 may be disposed on the first board 110. The second board 120 may be disposed to be spaced apart from the one surface of the first board 110, on which the electronic components are disposed, by a specific distance. The electronic component may be disposed on one surface of the second board 120. The electronic components on the first board 110 and the second board 120 may face each other.

The second board 120 may be disposed to cover at least a portion of the first board 110. The second board 120 may be formed to be smaller than the first board 110. The shapes of the first board 110 and the second board 120, as illustrated in FIG. 2, are provided for the illustrative purpose, and the first board 110 and the second board 120 may have various shapes and sizes.

The wirings may include one or more signal lines to apply control signals to the electronic elements mounted on the first board 110 or the second board 120 and one or more ground areas for grounding. The wirings may be printed on the first board 110 and the second board 120. The first board 110 and the second board 120 may form printed circuit boards including the wirings.

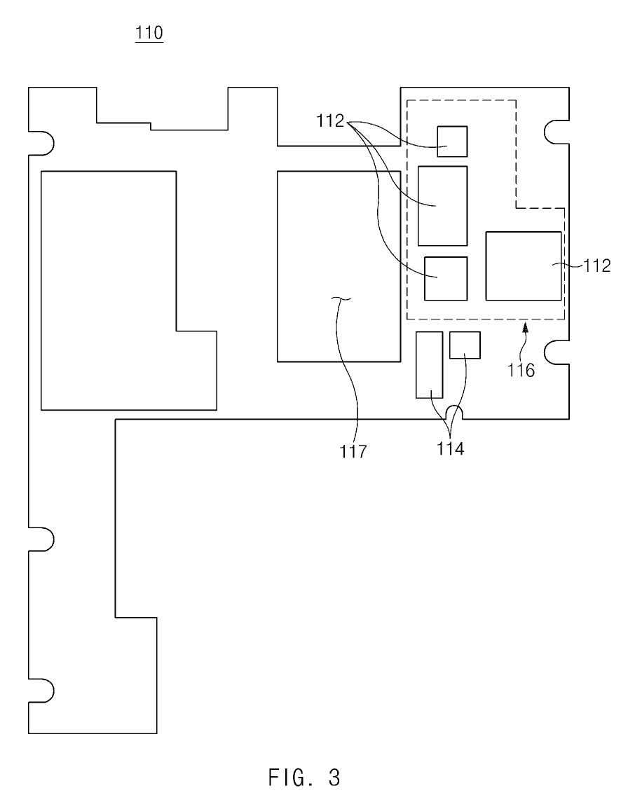

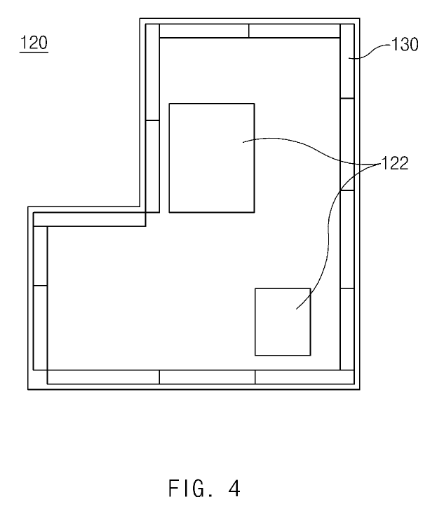

FIG. 3 is a plan view of the first board of the electronic device, according to an embodiment, and FIG. 4 is a plan view of the second board of the electronic device, according to an embodiment.

Referring to FIG. 3, a camera mounting hole 117 for mounting a camera may be formed in the first board 110.

The first board 110 and the second board 120 may be stacked on each other in a shielding space 116 marked by a dotted line of FIG. 3. As described below, the ground area included in the first board 110, the ground area included in the second board 120, and the connector 130 between the first board 110 and the second board 120 may be electrically connected together, and the shielding space 116 may be formed by the electrical connection.

Referring to FIG. 4, a plurality of connectors 130 are arranged along the edge of the second board 120. The connectors 130 may be arranged to surround at least a partial area of the second board 120. The connectors 130 may be disposed to be adjacent to each other. The connectors 130 may be spaced apart from each other by a specific distance. The connectors 130 may be integrated with each other. For example, the connectors 130 may be disposed at the edge of the second board 120 to surround the second board 120 and may have a shape corresponding to the shape of the second board 120.

The electronic components may be disposed on the one surface of the first board 110 and on the one surface of the second board 120 facing the one surface of the first board 110. The electronic components may include first electronic components 112 disposed on the first board 110 and positioned inside the shielding space 116, second elements 122 disposed on the second board 120 and positioned inside the shielding space 116, and third electronic components 114 disposed on the first board 110 and positioned outside the shielding space 116. The positions and the number of the electronic components are not limited to the positions and the number of the electronic components illustrated in the drawing. The drawing is provided for the illustrative purpose and each electronic component may include a plurality of electronic components.

The second elements 122 disposed on the second board 120 may be disposed at positions corresponding to positions of the first electronic components 112.

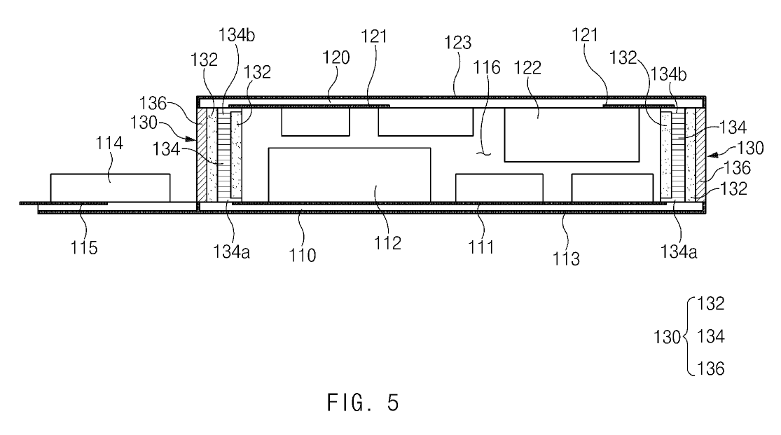

FIG. 5 is a sectional view of the shielding space of the electronic device, according to an embodiment.

Referring to FIG. 5, the connectors 130 constitute outer sidewalls of the second board 120 and a partial area of the first board 110 corresponding to the second board 120.

An area in which the electrical elements in the second board 120 surrounded by the connectors 130 are positioned may be referred to as an inside of the connectors 130, when viewed with reference to the connector 130.

The connector 130 may include an insulating member 132, a conductive pin 134, and a metal plate 136. The second electronic components 122 in the second board 120 may be positioned at the inside of the connector 130. The metal plate 136 may be formed on an outer surface, in which the edge of the second board 120 is provided, of the side surfaces of the connector 130.

A plurality of connectors 130 may cover the space between the first board 110 and the second board 120 disposed on the first board 110. An internal space surrounded by the connectors 130 may be formed between the first board 110 and the second board 120. The metal plate 136 formed on the outer side surface of each of the connectors 130 may cover the space between the first board 110 and the second board 120. The shielding space 116 surrounded by metal plates 136 formed on the connectors 130 may be formed between the first board 110 and the second board 120.

The metal plate 136 may be formed on the outer surface of the connector 130 to cover one or more second electronic components 122 formed in the second board 120, one or more first electronic components 112 formed in the partial area of the first board 110 corresponding to the second board 120; and a plurality of conductive pins 134 included in one or more connectors 130.

The first board 110 may include a first signal line 111, which has at least a portion formed at an area corresponding to the second board 120, and a first ground area 113. The second board 120 may include a second signal line 121 and a second ground area 123. Additionally, the first board 110 may include a third signal line 115 formed outside the shielding space 116. The third electronic component 114 may be connected with the third signal line 115.

The first electronic component 112 may be connected with the first signal line 111 and the second electronic component 122 may be connected with the first signal line 111, the conductive pin 134, and the second signal line 121. The first signal line 111 may be connected with the third electronic component 114 and/or the third signal line 115 disposed outside the shielding space 116.

The metal plate 136 may be electrically connected with the first ground area 113 and the second ground area 123. Accordingly, the shielding space 116 may be formed between the first board 110 and the second space 120. The shielding space 116 may block electromagnetic noises such as electromagnetic waves generated from the first electronic component 112, the second electronic component 122, the first signal line 111, the second signal line 121, and the conductive pin 134, which are positioned inside the shielding space 116, from being discharged to the outside of the shielding space 116. Alternatively, the shielding space 116 may block electromagnetic noises that are present outside the shielding space 116 from being introduced into the shielding space 116.

The shielding space 116 may include, on the inside of the shielding space 116, electronic components formed, mounted, or disposed on one surface of the second board 120 and/or one surface of the first board 110 facing the one surface of the second board 120. The first board 110 and the second board 120 may include areas, which are for forming or disposing an electronic component, at a respective one surface thereof. The electronic components may include the first electronic component 112 disposed on the first board 110 and positioned inside the shielding space 116, the second electronic component 122 disposed on the second board 120 and positioned inside the shielding space 116, and the third electronic component 114 disposed on the first board 110 and positioned outside the shielding space 116. The first electronic component 112 and the second electronic component 122 may be formed on respective boards to face each other. When viewed based on the sectional view, the first electronic component 112 may be arranged to be offset from the second electronic component 122. The first electronic component 112 and the second electronic component 122 may be arranged to be in a zig-zag pattern.

The electronic component may include a fourth electronic component disposed on the second board 120 and positioned outside the shielding space 116. In addition, the second board 120 may be provided on one surface thereof with the second electronic component 122 and provided on an opposite surface thereof with the fourth electronic component. For example, the fourth electronic component may be an electronic component which does not cause electromagnetic noises. Additionally, the fourth electronic component may be an electronic component less causing noises than the first electronic component 112 or the second electronic component 122 positioned inside the shielding space 116.

The connectors 130 may include a first connector and a second connector. The first connector may include a conductive pin 134 electrically connected with the first signal line 111 included in the first board 110 and the second signal line 121 included in the second board 120. The first connector may be electrically connected with the first electronic component 112 and the second electronic component 122 through the first signal line 111 and the second signal line 121.

The first connector may include the conductive pin 134, and a first end portion 134a making contact with the first signal line 111 and a second end portion 134b making contact with the second signal line 121. The first end portion 134a may be electrically connected with the first signal line 111 and the second end portion 134b may be electrically connected with the second signal line 121. Accordingly, the first electronic component 112 and the second electronic component 122 may be electrically connected with each other.

The first connector may include the metal plate 136 electrically connected with the first ground area 113 included in the first board 110 and the second ground area 123 included in the second board 120. As described above, the metal plate 136 may be disposed at the outer surface of the connector 130 to surround the shielding space 116.

The second connector may include the conductive pin 134, and the conductive pin 134 may not be connected with a signal line of the first board 110 and a signal line of the second board 120. Alternatively, the second connector may not include the conductive pin 134. The second connector may include the metal plate 136 electrically connected with the ground areas of the first board 110 and the second board 120. As described above, the metal plate 136 may be disposed on the outer surface of the connector 130 to surround the shielding space 116.

In other words, some of the connectors 130 may connect a signal line of the first board 110 with a signal line of the second board 120, but remaining connectors 130 may not connect a signal line of the first board 110 with a signal line of the second board 120. However, the connectors 130 may at least be connected with the ground areas of the first board 110 and the second board 120. Even the second connector, which is not electrically connected with the signal lines 111 and 121, is electrically connected with the ground areas 113 and 123 of the first board 110 and the second board 120 to form the shielding space 116.

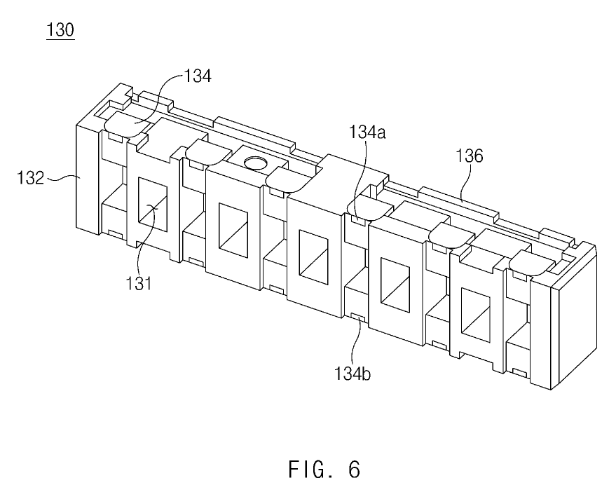

FIG. 6 is a perspective view of the connector of the electronic device, according to an embodiment.

Referring to FIG. 6, the connector 130 may be interposed between the first board 110 and the second board 120. The connector 130 may include the insulating member 132, the conductive pin 134 having at least a portion surrounded by the insulating member 132, and the metal plate 136 formed on one surface of the insulating member 132.

The connector 130 may include an insulating member 132, a through hole formed through the insulating member 132, a conductive pin 134 disposed in the through hole, and a metal plate 136 to surround the insulating member 132. In this case, the conductive pin 134 may extend from a first surface (e.g., a top surface) of the insulating member 132 to a second surface (e.g., a bottom surface).

The insulating member 132 may include the first surface, the second surface facing the first surface, a third surface interposed between the first surface and the second surface, and a fourth surface facing the third surface. The first surface may be a top surface, the second surface may be a bottom surface, and the third surface may be a side surface interposed between the top surface and the bottom surface. For example, the third surface may be a side surface with a wider area than the top surface and/or bottom surface. Alternatively, the third surface may be parallel to the lengthwise direction of the insulating member 132.

The insulating member 132 may be formed in a rectangular parallelepiped shape. The insulating member 132 is formed in the third surface thereof with grooves 131 spaced apart from each other by a specific distance. At least a portion of the conductive pin 134 may be exposed through at least one of the grooves 131.

The first surface of the insulating member 132 may be disposed on a board, and the second surface of the insulating member 132 may be disposed on another board stacked on the board. For example, the first surface may be disposed on a first board 110 and the second surface may be disposed on a second board 120. Accordingly, the first board 110 and the second board 120 of FIG. 5 may be spaced apart from each other by the height of the insulating member 132.

A plurality of conductive pins 134 may be formed, and at least a portion of each conductive pin 134 may be surrounded by the insulating member 132. At least some of the conductive pins 134 may be formed inside the insulating member 132.

The conductive pins 134 may be connected with signal lines (e.g., the first signal line 111 and the second signal line 121 of FIG. 5) of the first board 110 and the second board 120. Referring to FIG. 5, electrical signals of the first board 110 and/or the second board 120 may be electrically connected with each other through the conductive pins 134.

The conductive pins 134 may be spaced apart from each other by a specific distance in a lengthwise direction of the insulating member 132. The conductive pins 134 may be formed to collectively be a number corresponding to the number of the grooves 131 formed in the third surface of the insulating member 132.

Lengthwise opposite end portions 134a and 134b of the conductive pin 134 may be formed on the first surface and the second surface of the insulating member 132, respectively. The first end portion 134a of the conductive pin 134 may be formed on the first surface of the insulating member 132 and the second end portion 134b of the conductive pin 134 may be formed on the second surface of the insulating member 132. The first end portion 132a and the second end portion 132b may extend in the direction of the third surface or the fourth surface of the insulating member 132.

Referring to FIG. 5, the first end portion 134a may be electrically connected with the first signal line 111 and the second end portion 134b may be electrically connected with the second signal line 121.

When viewed in the sectional view taken perpendicularly to the lengthwise direction of the insulating member 132, the insulating member 132 may be provided in a rectangular shape and the conductive pin 134 may be provided in a substantially “C” shape.

The metal plate 136 may be formed on one side surface of the insulating member 132. Alternatively, the metal plate 136 may be formed on another side surface, which has a longer length than side surfaces of the insulating member 132. The metal plate 136 may be electrically connected with the ground areas of the first board 110 and the second board 120. A plurality of electronic components disposed or formed on the first board 110 and the second board 120 may be grounded by the metal plate 136. The metal plate 136 may be formed on a portion of the third surface of the insulating member 132 and/or the metal plate 136 may be formed at an area facing a direction perpendicular to the extending direction of the conductive pins 134.

Referring to the sectional surface of the shielding space 116 illustrated in FIG. 5, the electronic elements may be disposed inside the shielding space 116. At least one second electronic component 122 may be disposed on the second board 120 inside the shielding space 116. The first electronic component 112 may be disposed on the first board 110 inside the shielding space 116.

The third electronic component 114 may be disposed on the first board 110 outside the shielding space 116. The third electronic component 114 may include a processor. A memory module may be disposed on the second board 120 inside the shielding space 116. The second electronic component 122 may include a memory module.

The memory module may have a data transfer rate of about 1 gigabits per second (Gbps) or more. To implement such a data transfer rate, the memory module may input or output an electrical signal having a frequency band higher than that of a different electronic component.

The memory module and the signal line connected with the memory module may cause electromagnetic noises having higher levels due to the electrical signal having the higher frequency band. The electromagnetic noises may interrupt the normal operation of the electronic device 100. The electromagnetic device of the present disclosure may block noises from being discharged to the outside, as the memory module is disposed inside the shielding space 116.

The electronic device 100 including the connector 130 may include the second board 120 having the memory module mounted thereon and the first board 110 having a processor mounted thereon to control the memory module and improve a data transfer rate. Meanwhile, the electronic device 100 may include one board (e.g., the first board 110) having a memory module and a processor mounted thereon.

In addition, the memory module may be mounted on the second board 120, and may be connected with the processor on the first board 110 by using the conductive pin 134 of the connector 130.

TABLE 1

| | | |
|---|---|---|
| | | (Embodiment − |
| | | Comparative example)/ |
| | | Comparative |
| Classification | The number of | example * 100 |

| File Format | times of tests | Read rate | Write rate |
|---|---|---|---|
| MP3 | 1 | −2% | 0% |
| | 2 | 0% | 0% |
| | 3 | 0% | 1% |
| | Average | −1% | 0% |
| Moving | 1 | −2% | −2% |
| picture | 2 | 7% | 0% |
| | 3 | 2% | −1% |
| | Average | 2% | −1% |

Comparative example: Processor and memory module are disposed on the same board.

Embodiment: Processor and memory module are disposed on different boards and are electrically connected by the connector 130. For example, the processor may be disposed on the first board 110, and the memory module may be disposed on the second board 120. The first board 110 and the second board 120 are stacked and the connector 130 can be disposed therebetween.

It may be recognized, based on Table 1 above, that there is a significant difference in the read and write rates of the memory module between the case in which the memory module is disposed on the second board (without the processor) and the case in which the memory module and the processor are disposed on the same board. In other words, it may be recognized that the conductive pin 134 of the connector 130 is suitable for the high data transfer rate of the memory module.

Through this, it can be seen that the disclosed connector 130 can connect the processor and the memory module without significant speed degradation.

The signal line 111 of the first board 110 and the signal line 121 of the second board 120 may be operatively and electrically connected with each other through the connector 130. In addition, the shielding space 116 defined by the ground area 123 of the second board 120, the ground area 113 of the first board 110 corresponding to the second board 120, and the metal plate 136 of the connector 130 may successfully shield the electromagnetic noises caused by the memory module.

Although the aforementioned example relates to the data transfer rate of the memory module, the result may be similarly applied to another electronic component. In general, a similar result may be applicable to another electronic component even if the other electronic component is mounted on the second board 120 and operates at a frequency lower than that of the memory module.

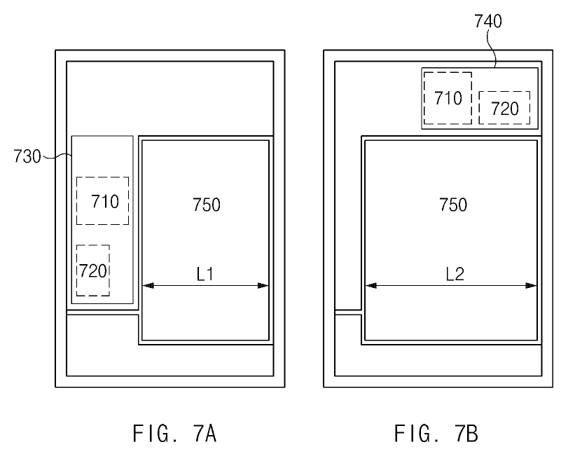

FIGS. 7A and 7B illustrate the layout of the board and the battery of the electronic device, according to an embodiment. FIG. 7A is a view illustrating the layout of a main board of a conventional electronic device, and FIG. 7B is a view illustrating the layout of a main board of an electronic device, according to an embodiment.

As illustrated in FIG. 7A, the conventional electronic device may include a plurality of electronic components disposed on the main board and may additionally include a shielding member 730 to effectively shield the electromagnetic interference caused by electronic components 710 and 720, which comprise some of the electronic components. The shielding member 730 may include a shield can. The electronic component shielded by the shielding member 730 may include a processor, a memory module, or a high-rate communication module, operating at a high frequency.

Meanwhile, according to an embodiment as illustrated in FIG. 7B, the electronic device may include a sub-board 740 stacked on a main board and a connector 130 electrically connecting the main board with the sub-board 740. The electronic components 710 and 720 formed on the main board may be electromagnetically shielded by the sub-board 740 and the connector. As described above, the grounds of the main board and the sub-board 740, and the metal plate 136 of the connector 130 may define the shielding space.

An electronic component (e.g., a memory module), which may cause the electromagnetic interference, is disposed inside such a shielding space 116, thereby blocking the electromagnetic interference without a separate shielding member. Accordingly, the mounting area for the electronic component is reduced from the board, so battery areas L1 and L2 may be increased.

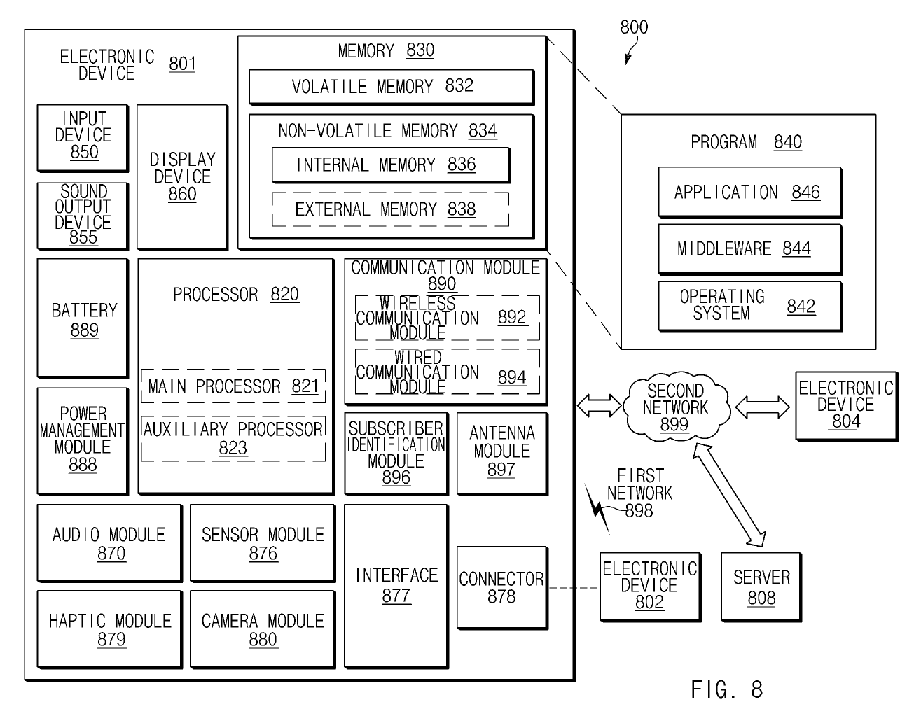

FIG. 8 is a block diagram illustrating an electronic device 801 in a network environment 800 according to various embodiments. Referring to FIG. 8, the electronic device 801 in the network environment 800 may communicate with an electronic device 802 via a first network 898 (e.g., a short-range wireless communication network), or an electronic device 804 or a server 808 via a second network 899 (e.g., a long-range wireless communication network). According to an embodiment, the electronic device 801 may communicate with the electronic device 804 via the server 808. According to an embodiment, the electronic device 801 may include a processor 820, memory 830, an input device 850, a sound output device 855, a display device 860, an audio module 870, a sensor module 876, an interface 877, a haptic module 879, a camera module 880, a power management module 888, a battery 889, a communication module 890, a subscriber identification module (SIM) 896, or an antenna module 897. In some embodiments, at least one (e.g., the display device 860 or the camera module 880) of the components may be omitted from the electronic device 801, or one or more other components may be added in the electronic device 801. In some embodiments, some of the components may be implemented as single integrated circuitry. For example, the sensor module 876 (e.g., a fingerprint sensor, an iris sensor, or an illuminance sensor) may be implemented as embedded in the display device 860 (e.g., a display).

The processor 820 may execute, for example, software (e.g., a program 840) to control at least one other component (e.g., a hardware or software component) of the electronic device 801 coupled with the processor 820, and may perform various data processing or computation. According to one embodiment, as at least part of the data processing or computation, the processor 820 may load a command or data received from another component (e.g., the sensor module 876 or the communication module 890) in volatile memory 832, process the command or the data stored in the volatile memory 832, and store resulting data in non-volatile memory 834. According to an embodiment, the processor 820 may include a main processor 821 (e.g., a central processing unit (CPU) or an application processor (AP)), and an auxiliary processor 823 (e.g., a graphics processing unit (GPU), an image signal processor (ISP), a sensor hub processor, or a communication processor (CP)) that is operable independently from, or in conjunction with, the main processor 821. Additionally or alternatively, the auxiliary processor 823 may be adapted to consume less power than the main processor 821, or to be specific to a specified function. The auxiliary processor 823 may be implemented as separate from, or as part of the main processor 821.

The auxiliary processor 823 may control at least some of functions or states related to at least one component (e.g., the display device 860, the sensor module 876, or the communication module 890) among the components of the electronic device 801, instead of the main processor 821 while the main processor 821 is in an inactive (e.g., sleep) state, or together with the main processor 821 while the main processor 821 is in an active state (e.g., executing an application). According to an embodiment, the auxiliary processor 823 (e.g., an image signal processor or a communication processor) may be implemented as part of another component (e.g., the camera module 880 or the communication module 890) functionally related to the auxiliary processor 823.

The memory 830 may store various data used by at least one component (e.g., the processor 820 or the sensor module 876) of the electronic device 801. The various data may include, for example, software (e.g., the program 840) and input data or output data for a command related thereto. The memory 830 may include the volatile memory 832 or the non-volatile memory 834.

The program 840 may be stored in the memory 830 as software, and may include, for example, an operating system (OS) 842, middleware 844, or an application 846.

The input device 850 may receive a command or data to be used by other component (e.g., the processor 820) of the electronic device 801, from the outside (e.g., a user) of the electronic device 801. The input device 850 may include, for example, a microphone, a mouse, a keyboard, or a digital pen (e.g., a stylus pen).

The sound output device 855 may output sound signals to the outside of the electronic device 801. The sound output device 855 may include, for example, a speaker or a receiver. The speaker may be used for general purposes, such as playing multimedia or playing record, and the receiver may be used for an incoming calls. According to an embodiment, the receiver may be implemented as separate from, or as part of the speaker.

The display device 860 may visually provide information to the outside (e.g., a user) of the electronic device 801. The display device 860 may include, for example, a display, a hologram device, or a projector and control circuitry to control a corresponding one of the display, hologram device, and projector. According to an embodiment, the display device 860 may include touch circuitry adapted to detect a touch, or sensor circuitry (e.g., a pressure sensor) adapted to measure the intensity of force incurred by the touch.

The audio module 870 may convert a sound into an electrical signal and vice versa. According to an embodiment, the audio module 870 may obtain the sound via the input device 850, or output the sound via the sound output device 855 or a headphone of an external electronic device (e.g., an electronic device 802) directly (e.g., wiredly) or wirelessly coupled with the electronic device 801.

The sensor module 876 may detect an operational state (e.g., power or temperature) of the electronic device 801 or an environmental state (e.g., a state of a user) external to the electronic device 801, and then generate an electrical signal or data value corresponding to the detected state. According to an embodiment, the sensor module 876 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 877 may support one or more specified protocols to be used for the electronic device 801 to be coupled with the external electronic device (e.g., the electronic device 802) directly (e.g., wiredly) or wirelessly. According to an embodiment, the interface 877 may include, for example, a high definition multimedia interface (HDMI), a universal serial bus (USB) interface, a secure digital (SD) card interface, or an audio interface.

A connecting terminal 878 may include a connector via which the electronic device 801 may be physically connected with the external electronic device (e.g., the electronic device 802). According to an embodiment, the connecting terminal 878 may include, for example, a HDMI connector, a USB connector, a SD card connector, or an audio connector (e.g., a headphone connector).

The haptic module 879 may convert an electrical signal into a mechanical stimulus (e.g., a vibration or a movement) or electrical stimulus which may be recognized by a user via his tactile sensation or kinesthetic sensation. According to an embodiment, the haptic module 879 may include, for example, a motor, a piezoelectric element, or an electric stimulator.

The camera module 880 may capture a still image or moving images. According to an embodiment, the camera module 880 may include one or more lenses, image sensors, image signal processors, or flashes.

The power management module 888 may manage power supplied to the electronic device 801. According to one embodiment, the power management module 888 may be implemented as at least part of, for example, a power management integrated circuit (PMIC).

The battery 889 may supply power to at least one component of the electronic device 801. According to an embodiment, the battery 889 may include, for example, a primary cell which is not rechargeable, a secondary cell which is rechargeable, or a fuel cell.

The communication module 890 may support establishing a direct (e.g., wired) communication channel or a wireless communication channel between the electronic device 801 and the external electronic device (e.g., the electronic device 802, the electronic device 804, or the server 808) and performing communication via the established communication channel. The communication module 890 may include one or more communication processors that are operable independently from the processor 820 (e.g., the application processor (AP)) and supports a direct (e.g., wired) communication or a wireless communication. According to an embodiment, the communication module 890 may include a wireless communication module 892 (e.g., a cellular communication module, a short-range wireless communication module, or a global navigation satellite system (GNSS) communication module) or a wired communication module 894 (e.g., a local area network (LAN) communication module or a power line communication (PLC) module). A corresponding one of these communication modules may communicate with the external electronic device via the first network 898 (e.g., a short-range communication network, such as Bluetooth™, wireless-fidelity (Wi-Fi) direct, or infrared data association (IrDA)) or the second network 899 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 892 may identify and authenticate the electronic device 801 in a communication network, such as the first network 898 or the second network 899, using subscriber information (e.g., international mobile subscriber identity (IMSI)) stored in the subscriber identification module 896.

The antenna module 897 may transmit or receive a signal or power to or from the outside (e.g., the external electronic device) of the electronic device 801. According to an embodiment, the antenna module 897 may include an antenna including a radiating element composed of a conductive material or a conductive pattern formed in or on a substrate (e.g., PCB). According to an embodiment, the antenna module 897 may include a plurality of antennas. In such a case, at least one antenna appropriate for a communication scheme used in the communication network, such as the first network 898 or the second network 899, may be selected, for example, by the communication module 890 (e.g., the wireless communication module 892) from the plurality of antennas. The signal or the power may then be transmitted or received between the communication module 890 and the external electronic device via the selected at least one antenna. According to an embodiment, another component (e.g., a radio frequency integrated circuit (RFIC)) other than the radiating element may be additionally formed as part of the antenna module 897.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 801 and the external electronic device 804 via the server 808 coupled with the second network 899. Each of the electronic devices 802 and 804 may be a device of a same type as, or a different type, from the electronic device 801. According to an embodiment, all or some of operations to be executed at the electronic device 801 may be executed at one or more of the external electronic devices 802, 804, or 808. For example, if the electronic device 801 should perform a function or a service automatically, or in response to a request from a user or another device, the electronic device 801, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 801. The electronic device 801 may provide the outcome, with or without further processing of the outcome, as at least part of a reply to the request. To that end, a cloud computing, distributed computing, or client-server computing technology may be used, for example.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 840) including one or more instructions that are stored in a storage medium (e.g., internal memory 836 or external memory 838) that is readable by a machine (e.g., the electronic device 801). For example, a processor(e.g., the processor 820) of the machine (e.g., the electronic device 801) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

As described above, even if the separate shielding member, such as the shielding can, is not used, an electronic part inside the electronic device may be shielded in such a manner that the electronic part is operable. Accordingly, the size of the board may be reduced and the utilization of the internal space of the electronic device may be increased. As the size of the board is reduced, the capacity of the battery may be increased.

Besides, a variety of effects directly or indirectly understood through the disclosure may be provided.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a housing;
a first board disposed inside the housing and including a first signal line and a first ground;
a second board disposed on the first board and including a second signal line and a second ground;
a plurality of connectors interposed between the first board and the second board; and
a first electronic component disposed inside a space defined by the first board, the second board, and the plurality of connectors,
wherein each of the plurality of connectors includes:
an insulating member;
at least one conductive pin having at least a portion surrounded by the insulating member; and
a metal plate electrically connected with the first ground of the first board and the second ground of the second board and formed on an outer sidewall of the insulating member,
wherein a first signal pin of conductive pins included in the plurality of connectors is electrically connected with the first signal line of the first board, the second signal line of the second board, and the first electronic component, and
wherein the first electronic component is electrically shielded against an outside of the space by the first ground of the first board, the second ground of the second board, and the metal plate.

2. The electronic device of claim 1, further comprising:
a second electronic component disposed inside the space,
wherein the second electronic component is electrically connected with a third signal line included in the first board.

3. The electronic device of claim 2, wherein the second electronic component is electrically shielded against the outside of the space by the first ground of the first substrate, the second ground of the second substrate, and the metal plate.

4. The electronic device of claim 1, wherein the first electronic component is disposed on the second board.

5. The electronic device of claim 2, wherein the second electronic component is disposed on the first board.

6. The electronic device of claim 2, wherein the first electronic component is disposed on one surface of the first board, and the second electronic component is disposed on one surface of the second board facing the one surface of the first board.

7. The electronic device of claim 2, wherein the first electronic component and the second electronic component are offset from each other at an inside of the space.

8. The electronic device of claim 1, further comprising:
a third electronic component disposed at the outside of the space,
wherein the third electronic component is electrically connected with the first electronic component through the first signal line, the second signal line, and the first signal pin.

9. The electronic device of claim 1, wherein the first electronic component includes a memory module.

10. The electronic device of claim 8, wherein the first electronic component includes a memory module, and
wherein the third electronic component includes a processor to control the memory module.

11. The electronic device of claim 1, wherein the plurality of connectors are disposed to surround the first electronic component.

12. The electronic device of claim 1, wherein the plurality of connectors are disposed along an edge of the second board.

13. The electronic device of claim 1, wherein the conductive pins are spaced apart from each other by a specific distance.

14. A connector comprising:
an insulating member including a first surface, a second surface facing the first surface, and a third surface interposed between the first surface and the second surface;
a plurality of conductive pins, each conductive pin including at least a portion surrounded by the insulating member and opposite end portions formed on the first surface and the second surface, respectively; and
a metal plate formed on the third surface.

15. The connector of claim 14, wherein the metal plate is formed on an area, which faces a direction perpendicular to an extending direction of the conductive pins, of the third surface.

16. The connector of claim 14, wherein the plurality of conductive pins are spaced apart from each other by a specific distance.

17. The connector of claim 14, wherein the insulating member further includes:
a fourth surface facing the third surface, and
wherein the opposite end portions of the conductive pin extend in a direction of the fourth surface from the first surface and the second surface.

18. The connector of claim 14, wherein the insulating member further includes:
a fourth surface facing the third surface, and
wherein a plurality of grooves are formed in the fourth surface such that at least a portion of each conductive pin is exposed.

19. The connector of claim 14, wherein the insulating member includes:
a plurality of through holes formed through the first surface and the second surface, and
wherein the plurality of conductive pins are inserted into the plurality of through holes, respectively.

20. The connector of claim 14, wherein a first surface-side end portion and a second surface-side end portion of the metal plate are connected with a ground of at least one board.
